(19) United States
(12) Patent Application Publication
(10) Pub. No.: US 2026/0090325 A1
(43) Pub. Date: Mar. 26, 2026

(54) IN-SITU WAFER MONITORING WITH DYNAMIC BACKSIDE GAS FEEDBACK CONTROL AS WAFER BOW COUNTERMEASURE

(71) Applicant: Tokyo Electron Limited, Tokyo (JP)

(72) Inventors: Scott LEFEVRE, Albany, NY (US); Joshua BAILLARGEON, Albany, NY (US)

(73) Assignee: Tokyo Electron Limited, Tokyo (JP)

(21) Appl. No.: 18/897,591

(22) Filed: Sep. 26, 2024

(51) Int. Cl. H01L 21/67; H01L 21/683

(52) U.S. Cl. CPC H10P 72/0616; H10P 72/72

(57) ABSTRACT

Aspects of the present disclosure provide an electrostatic chuck (ESC)/backside gas (BSG) system. For example, the ESC/BSG system can include an ESC and a BSG cooling device integrated with the ESC. The ESC can be configured to generate an electrostatic chucking force according to an electrostatic voltage applied thereto to clamp a semiconductor structure with a backside placed onto the ESC. The BSG cooling device can be configured to introduce to the backside of the semiconductor structure a backside gas at a backside gas pressure. The ESC/BSG system can further include a monitoring system configured to monitoring bowing of the semiconductor structure, and a controller coupled between the monitoring system and the ESC and the BSG cooling device. The controller can be configured to adjust the electrostatic voltage and/or the backside gas pressure according to the bowing of the semiconductor structure.

### FIELD OF THE INVENTION

The present disclosure relates to semiconductor fabrication, and, more particularly, to wafer monitoring with dynamic backside gas feedback control as wafer bow countermeasure.

### BACKGROUND

The background description provided herein is for the purpose of generally presenting the context of the disclosure. Work of the presently named inventors, to the extent the work is described in this background section, as well as aspects of the description that may not otherwise qualify as prior art at the time of filing, are neither expressly nor impliedly admitted as prior art against the present disclosure.

Semiconductor fabrication involves multiple varied steps and processes. One typical fabrication process is known as photolithography (also called microlithography). Photolithography uses radiation, such as ultraviolet or visible light, to generate fine patterns in a semiconductor device design. Many types of semiconductor devices, such as diodes, transistors, and integrated circuits, can be constructed using semiconductor fabrication techniques including photolithography, etching, film deposition, surface cleaning, metallization, and so forth.

Different materials and structural formations formed onto the frontside of a substrate (or wafer) of a semiconductor structure can cause internal stresses in the substrate, which result in bowing of the semiconductor structure. This bowing can be counteracted with targeted deposition films on the backside of the substrate. However, during an etching process the balance of the frontside and backside film stresses will fall back out of equilibrium and can cause significant wafer warpage during processing leading to chucking failures, wafer breaks, and arcing events among others.

### SUMMARY

Aspects of the present disclosure provide an electrostatic chuck (ESC)/backside gas (BSG) system. For example, the ESC/BSG system can include an ESC configured to generate an electrostatic chucking force (ESC force) according to an electrostatic voltage applied thereto to clamp a semiconductor structure with a backside placed onto the ESC. The ESC/BSG system can further include at least one BSG cooling device integrated with the ESC. The at least one BSG cooling device can be configured to introduce to the backside of the semiconductor structure a backside gas at a backside gas pressure (BSG pressure). The ESC/BSG system can further include a monitoring system configured to monitoring bowing of the semiconductor structure. The ESC/BSG system can further include a controller coupled between the monitoring system and the ESC and the at least one BSG cooling device, the controller configured to adjust the BSG pressure at which the backside gas is introduced according to the bowing of the semiconductor structure.

In an embodiment, the monitoring system can include a light source configured to emit incident light onto a surface of the semiconductor structure, and a light detector configured to receive reflective light from the surface of the semiconductor structure and identify the bowing of the semiconductor structure. For example, the light detector can be configured to identify the bowing of the semiconductor structure by measuring z-direction height deviations across the surface of the semiconductor structure. In another embodiment, the monitoring system can include a leak-by flow gauge configured to measure a leak-by flow of the backside gas, the leak-by flow measured as a gauge for clamp performance of the ESC to the semiconductor structure that corresponds to the bowing of the semiconductor structure.

In some embodiments, the controller can be further configured to adjust the electrostatic voltage applied to the ESC according to the bowing of the semiconductor structure. In various embodiments, the ESC can include an electrode and a dielectric layer that is formed between the electrode and the semiconductor structure, and the electrostatic voltage is applied to the dielectric layer.

In an embodiment, the backside gas can be used to adjust temperature of the semiconductor structure. For example, the backside gas can include inert gas. As another example, the inert gas can include helium (He). In some embodiments, the at least one BSG cooling device can include multiple BSG cooling devices, and the controller can be configured to adjust BSG pressures at which the backside gas is introduced by the multiple BSG cooling devices according to the bowing of the semiconductor structure at multiple zones thereof.

Aspects of the present disclosure provide an electrostatic chuck (ESC)/backside gas (BSG) system. For example, the ESC/BSG system can include an ESC configured to generate an electrostatic chucking force (ESC force) according to an electrostatic voltage applied thereto to clamp a semiconductor structure with a backside placed onto the ESC. The ESC/BSG system can further include at least one BSG cooling device integrated with the ESC, the at least BSG cooling device configured to introduce to the backside of the semiconductor structure a backside gas at a backside gas pressure (BSG pressure). The ESC/BSG system can further include a monitoring system configured to monitoring bowing of the semiconductor structure. The ESC/BSG system can further include a controller coupled between the monitoring system and the ESC and the at least one BSG cooling device, the controller configured to adjust the electrostatic voltage applied to the ESC according to the bowing of the semiconductor structure.

In some embodiments, the controller can be further configured to adjust the BSG pressure at which the backside gas is introduced according to the bowing of the semiconductor structure.

Note that this summary section does not specify every embodiment and/or incrementally novel aspect of the present disclosure or claimed invention. Instead, this summary only provides a preliminary discussion of different embodiments and corresponding points of novelty. For additional details and/or possible perspectives of the invention and embodiments, the reader is directed to the Detailed Description section and corresponding figures of the present disclosure as further discussed below.

### BRIEF DESCRIPTION OF THE DRAWINGS

Various embodiments of this disclosure that are proposed as examples will be described in detail with reference to the following figures, wherein like numerals reference like elements, and wherein:

FIGS. 1A-1C shows a semiconductor structure that is bowed initially, is flat after a stress-modification film is formed on a backside of a substrate that counters a stress induced by different materials and structural formations formed on a frontside of the substrate, and is bowed after the different materials and structural formations is removed;

FIG. 2 shows a leak-by flow of a cooling gas for a variety of semiconductor samples with different bow measurements when different electrostatic voltages are applied;

FIG. 3 shows an equilibrium bow for a semiconductor sample applied with different electrostatic voltages;

FIGS. 4A-4C show that air pockets may appear under a bowed semiconductor structure, chucking of the bowed semiconductor structure is disrupted, and etching to the bowed semiconductor structure is tilted, respectively;

FIGS. 5A-5D show a semiconductor structure with different bow measurements when thinned gradually under a static backside gas pressure;

FIGS. 6A-6D show a semiconductor structure that is substantially flat when thinned gradually under an adjusted backside gas pressure according to some embodiments of the present disclosure;

FIGS. 7A-7C are schematic diagrams illustrating an electrostatic chuck (ESC)/backside gas (BSG) system according to a first embodiment of the present disclosure;

FIGS. 8A-8C are schematic diagrams illustrating an ESC/BSG system according to a second embodiment of the present disclosure;

FIGS. 9A-9C are schematic diagrams illustrating an ESC/BSG system according to a third embodiment of the present disclosure; and

FIG. 10 shows a semiconductor structure including multiple zones that are arranged radially/angularly and measured for their bow measurements.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed. Further, spatially relative terms, such as “top,” “bottom,” “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The order of discussion of the different steps as described herein has been presented for clarity sake. In general, these steps can be performed in any suitable order. Additionally, although each of the different features, techniques, configurations, etc. herein may be discussed in different places of this disclosure, it is intended that each of the concepts can be executed independently of each other or in combination with each other. Accordingly, the present invention can be embodied and viewed in many different ways.

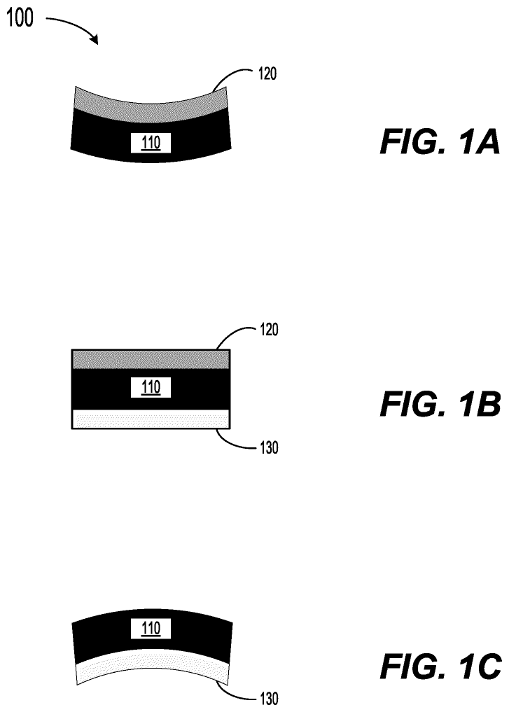

Microfabrication of a semiconductor structure 100 begins with a flat substrate or wafer 110. During microfabrication of the semiconductor structure 100, multiple processing steps are executed that can include depositing material on the substrate, etching and removing materials, implanting dopants, annealing, baking, and so forth. Different materials and structural formations 120 thus formed (e.g., on the frontside of the substrate 110) can cause internal stresses in the substrate 110, which result in bowing of the semiconductor structure 100, which in turn affects overlay and typically results in overlay errors of various magnitudes, as shown in FIG. 1A. For example, the different materials and structural formations 120 can either induce a compressive or tensile stress in the substrate 110, respectively, resulting in first order bowing of the substrate 110 with bow measurements illustrating positive or negative z-direction height deviations from a reference plane or resulting in second order bowing of the substrate 110 with two bow measurements identifying positive and negative z-direction height deviations, respectively.

If a region of the substrate 110 initially contains compressive stress or tensile stress, due to the different materials and structural formations 120, the opposite type of stress may be applied in a localized nano stress region. For example, a stress-modification film 130 having an internal stress that may be modified by, for example, heat or light (e.g., laser) according to the bow measurement of the substrate 110 can be deposited and formed on the backside of the substrate 110, in order to counter the induced internal stress and reduce an average z-direction height deviation of the substrate 110 such that the semiconductor structure 100 can be close to being flat or considered flat, as shown in FIG. 1B.

As the semiconductor structure 100 is further processed, e.g., the different materials and structural formations 120 being etched and removed, the stress-modification film 130, which remains on the backside of the substrate 110, now is responsible for creating the bowing of the substrate 110, which has an opposite z-direction height deviation to the substrate 110 shown in FIG. 1A, as shown in FIG. 1C.

Electrostatic chucks (ESCs) are used to clamp (or chuck) a semiconductor structure, e.g., the semiconductor structure 100, during various processing steps. In operation of an ESC, an electrostatic voltage is applied to a dielectric layer between the semiconductor structure 100 and an electrode, and an electrostatic chucking force (ESC force) is thus generated and can clamp the semiconductor structure 100 against the dielectric layer. The ESC may be integrated with a backside gas (BSG) cooling device that is used to control the temperature of the semiconductor structure 100 during the processing steps. The BSG cooling device can introduce an inert gas with high thermal conductivity, such as helium (He), as a cooling gas to the backside of the semiconductor structure 100.

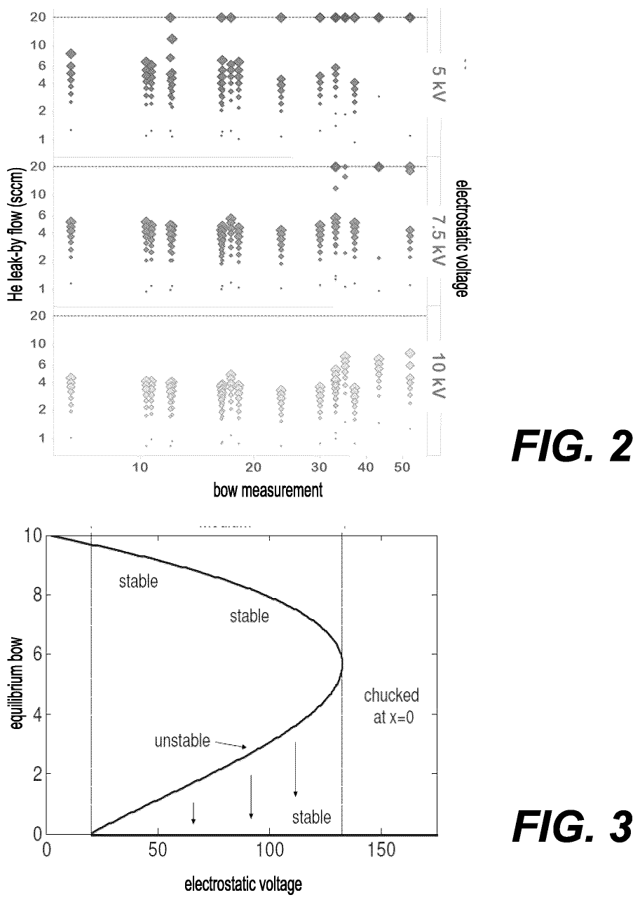

The clamp (or chuck) uniformity across the semiconductor structure 100 may determine the cooling efficiency of the ESC/BSG system. Leak-by flow of the cooling gas can be measured as a gauge for clamp (or chuck) performance. A high amount of leak-by flow indicates that the semiconductor structure 100 is not properly chucked (e.g., due to the bowing of the semiconductor structure 100) and therefore a great portion of the cooling gas does not reach the backside of the semiconductor structure 100; while a low amount of leak-by flow indicates that the semiconductor structure 100 is well chucked and the cooling efficiency of the ESC/BSG system is high. FIG. 2 shows the leak-by flow of the cooling gas for a variety of semiconductor samples (represented by dots at different backside gas (e.g., He) pressure (BSG pressure)) with different bow measurements when different electrostatic voltages are applied. FIG. 2 is from “Characterization of Electrostatic Chuck (ESC) Performance with Changes in Wafer Warpage and Backside Cooling Conditions,” by Saman Parizi et al., CS MANTECH Conference, May 9-12, 2022, which is incorporated herein for reference in its entirety. As shown, the higher amount of leak-by flow is seen for semiconductor samples with higher bow measurements, but higher electrostatic voltages and lower BSG pressure may mitigate the impact of the bowing of the semiconductor samples on the leak-by flow. Therefore, the semiconductor structure 100 with a high bow measurement can be well chucked under certain conditions such as a high ESC electrostatic voltage and/or by reducing the BSG pressure.

In the ESC/BSG system, a higher electrostatic voltage can cause a greater ESC force, which may overcome the bowing of the semiconductor structure 100 that is induced during the etching and removing of the different materials and structural formations 120 from the frontside of the semiconductor structure 100. FIG. 3 shows that the equilibrium bow is close to the initial bow (i.e., 10) at a low electrostatic voltage, and can be close to zero, which indicates that the semiconductor structure 100 can be chucked flat, when a high electrostatic voltage is applied such that an ESC force is generated that exceeds the elastic bow restoring force. FIG. 3 is from “Effect of wafer bow on electrostatic chucking and back side gas cooling,” by Daniel L. Goodman, Journal of Applied Physics 104. 124902 (2008), which is incorporated herein for reference in its entirety.

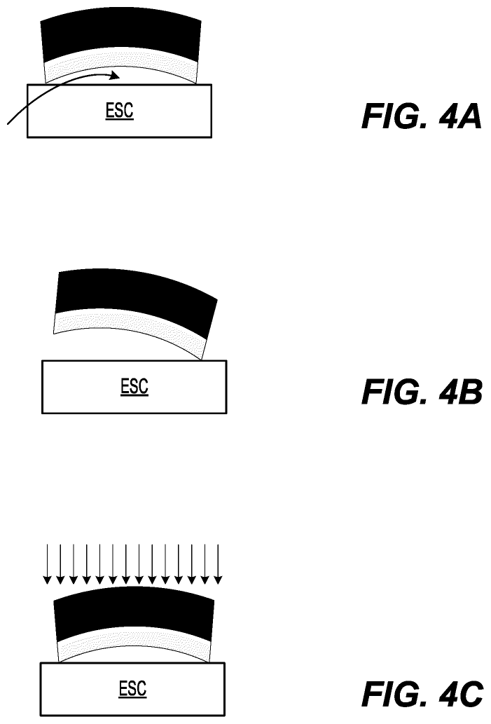

When the semiconductor structure 100 has an average z-direction height variation that cannot be ignored, e.g., the semiconductor structure 100 shown in FIG. 1C, and is placed onto a chuck of the ESC, small air pockets (indicated by an arrow) may appear under the bowed semiconductor structure 100, as shown in FIG. 4A, and arcing events may be created accordingly. The semiconductor structure 100, if significantly bowed, is likely to disrupt wafer chucking or even create movement/wafer break issues, as shown in FIG. 4B. The etching to the bowed semiconductor structure 100 is tilted at the edge thereof, and the distortion of the etching at the edge, no matter how minor it is, can alter the quality of the semiconductor structure 100, as shown in FIG. 4C.

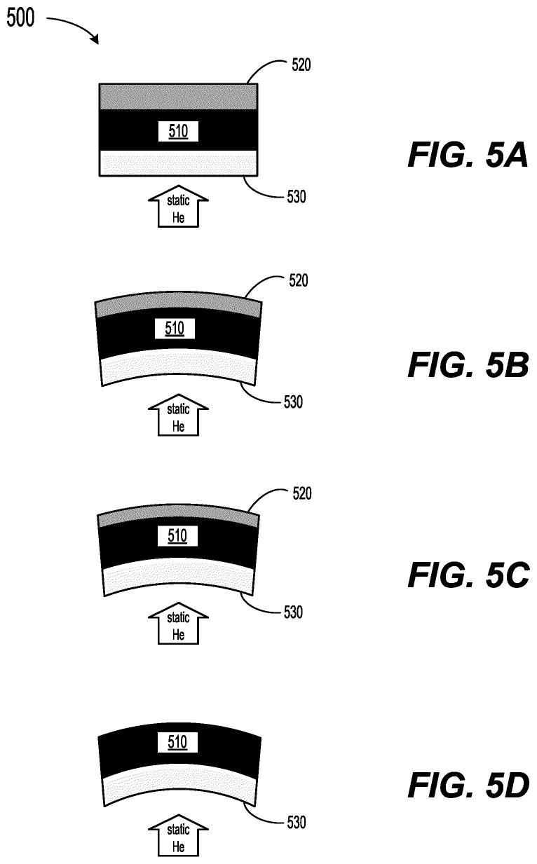

During etching and removing of different materials and structural formations 520 from the frontside of a substrate 510 of a semiconductor structure 500 (e.g., the semiconductor structure 100), if the backside gas (He) pressure and the electrostatic voltage are kept constant (or static), the bow measurement of the semiconductor structure 500 (caused by a stress-modification films 530 formed on the backside of the substrate 510) becomes greater and greater as more and more different materials and structural formations 520 are etched and removed from the frontside of the substrate 510, as shown in FIGS. 5A-5D.

The present disclosure can utilize BSG (He) pressure and ESC electrostatic voltage as dynamic parameters during processing (e.g., etching) to counter changes in stress from film thickness variations dur to the etch process rather than static BSG pressures.

The present disclosure can utilize a monitoring system (e.g., laser/detector) of changes in wafer shape with respect to bowing with a feedback control of BSG pressure and/or ESC electrostatic voltage as a stepwise or gradient control knob to help balance out the effect of change in wafer bowing during processing. The monitoring system can feedback the change in wafer shape (bow) over a recipe and allow for automatic adjustments of BSG pressure and ESC electrostatic voltage to help maintain better wafer chucking and flatter wafer surface to avoid dechucking faults and tilted etches.

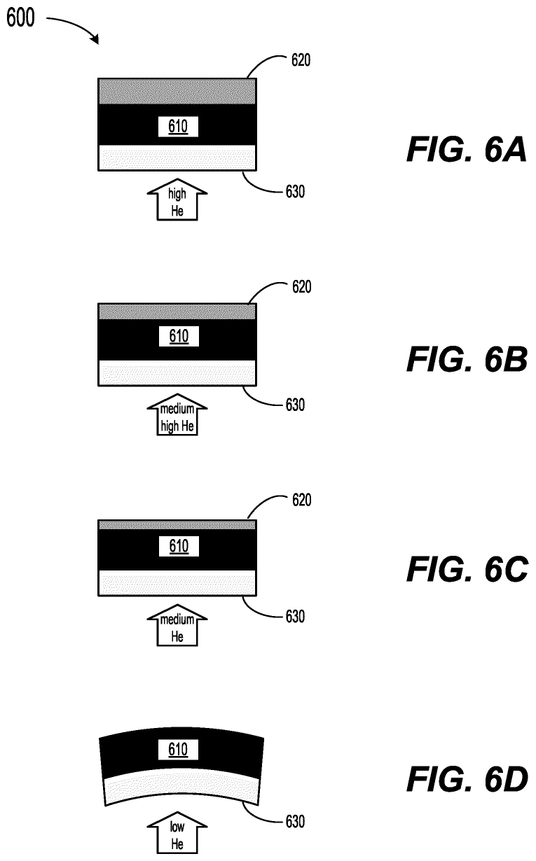

In an embodiment, the BSG pressure and/or ESC electrostatic voltage can be controlled and modified based on the bow measurement of a semiconductor structure 600 placed on an ESC and/or the leak-by flow of a cooling gas (i.e., a backside gas) in a BSG cooling device as different materials and structural formations 620 formed on the frontside of a substrate 610 is etched and removed gradually, as shown in FIGS. 6A-6D. For example, the backside gas in the BSG cooling device is at a high pressure (and/or the ESC electrostatic voltage is at a low level) initially when the semiconductor structure 600 is flat with a stress-modification film 630 formed on the backside of the substrate 610 to counter the stress induced by the different materials and structural formations 620, as shown in FIG. 6A; as the different materials and structural formations 620 is etched, the backside gas is changed to be at a medium high pressure (and/or the ESC electrostatic voltage is changed to be at a medium low level), in order to keep the semiconductor structure 600 flat, as shown in FIG. 6B; as the different materials and structural formations 620 is further etched, the backside gas is changed to be at a medium pressure (and/or the ESC electrostatic voltage is changed to be at a medium level), in order to keep the semiconductor structure 600 flat, as shown in FIG. 6C; and after the different materials and structural formations 620 is removed completely, the backside gas is changed to be at a low high pressure (and/or the ESC electrostatic voltage is changed to be at a high level), in order to keep the semiconductor structure 600 as flat as possible, as shown in FIG. 6D. The semiconductor structure 600 may have bow, as shown in FIG. 6D, or may not have bow, depending on stress and amount of He control. Lower backside gas (He) flow (e.g., the backside gas at a lower pressure) and/or higher ESC electrostatic voltage will cause less direct deflection of the semiconductor structure 600 and should allow for the ESC force to hold the semiconductor structure 600 tighter to the chuck, thus collapsing any significant sized “air pockets” under the semiconductor structure 600.

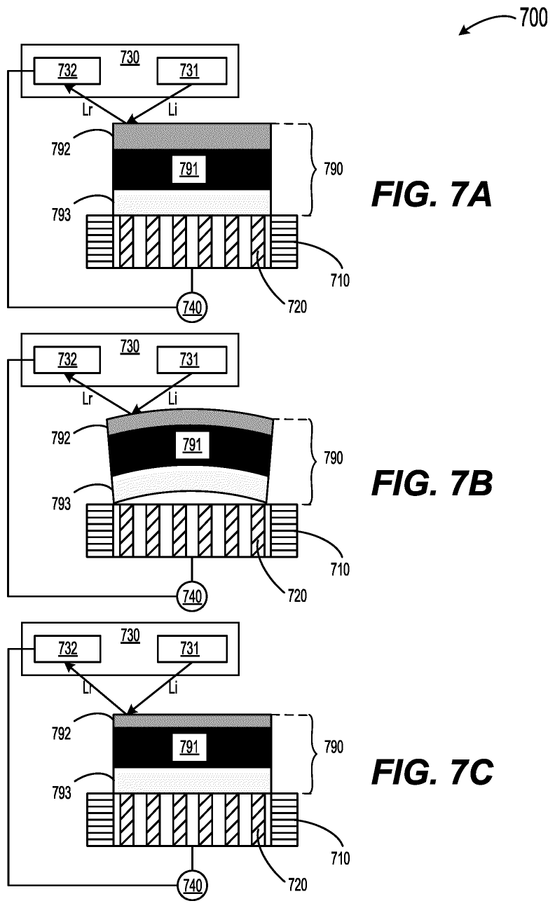

FIGS. 7A-7C are schematic diagrams illustrating an ESC/BSG system 700 according to a first embodiment of the present disclosure. The ESC/BSG system 700 can help balance out the effect of change in wafer bowing during processing. In an embodiment, the ESC/BSG system 700 can include an ESC 710 that is configured to clamp (or chuck) a semiconductor structure 790 (e.g., the semiconductor structures 100, 500 and 600) placed thereonto (or on a chuck thereof). For example, the ESC 710 can generate an ESC force according to an electrostatic voltage applied thereto (e.g., applied to a dielectric layer formed between an electrode and the semiconductor structure 790) to clamp the semiconductor structure 790.

In an embodiment, the ESC/BSG system 700 can further include a BSG cooling device 720 that is configured to control the temperature of the semiconductor structure 790. For example, the BSG cooling device 720 can introduce an inert gas with high thermal conductivity, such as helium (He), as a cooling gas to the backside of the semiconductor structure 790.

In an embodiment, the ESC/BSG system 700 can further include a monitoring system 730 that is configured to monitor the bowing of the semiconductor structure 790. In an embodiment, the monitoring system 730 can use optical (e.g., using a scanning laser technique), acoustic and other mechanisms to measure the z-direction height deviations across a surface (e.g., a top surface) of the semiconductor structure 790 and store the height deviations by (x, y) coordinates in order to identify a plurality of sub-bow measurements (x, y) of the bow measurement. The z-direction height deviations can be mapped at various resolutions depending on type of metrology equipment used and/or a resolution desired. For example, the monitoring system 730 can include a light source 731 that is configured to emit incident light Li onto a surface (e.g., a top surface) of the semiconductor structure 790 and a light detector 732 that is configured to receive reflective light Lr from the top surface of the semiconductor structure 790 and measure the z-direction height deviations across the top surface of the semiconductor structure 790 to identify a plurality of sub-bow measurements (x, y) of the bow measurement (i.e., bowing) of the semiconductor structure 790.

In an embodiment, the ESC/BSG system 700 can further include a controller (e.g., a processor) 740 that is coupled between the monitoring system 730 and the ESC 710 and the BSG cooling device 720 and configured to control the ESC 710 and/or the BSG cooling device 720 based on the bow measurement of the semiconductor structure 790 obtained and feedbacked by the monitoring system 730. For example, the controller 740 can be configured to adjust the electrostatic voltage applied to the ESC 710 based on the bow measurement of the semiconductor structure 790 in order to adjust the ESC force to clamp the semiconductor structure 790. As another example, the controller 740 can be configured to adjust the flow of the backside gas (or the BSG pressure of the backside gas (He)) of the BSG cooling device 720 based on the bow measurement (e.g., positive or negative bowing) of the semiconductor structure 790.

In operation of the ESC/BSG system 700, the semiconductor structure 790, which may include a stress-modification film 793 formed on the backside of a substrate 791 to counter a stress induced by different materials and structural formations 792 formed on the frontside of the substrate 791 and is substantially flat, can be placed onto the ESC 710, as shown in FIG. 7A. As the semiconductor structure 790 is further processed, e.g., the different materials and structural formations 792 being etched and thinned, the stress-modification film 793, which remains on the backside of the substrate 791, now is responsible for creating the bowing of the substrate 791, resulting in the bowing of the semiconductor structure 790, and the monitoring system 730 can monitor the bowing and identify the bow measurement of the semiconductor structure 790, as shown in FIG. 7B. Accordingly, the controller 740 can control the ESC 710 to adjust the electrostatic voltage to adjust the ESC force and/or control the BSG cooling device 720 to adjust the flow of the backside gas (or the BSG pressure of the backside gas (He)) based on the bow measurement of the semiconductor structure 790 in order to flatten the semiconductor structure 790, as shown in FIG. 7C.

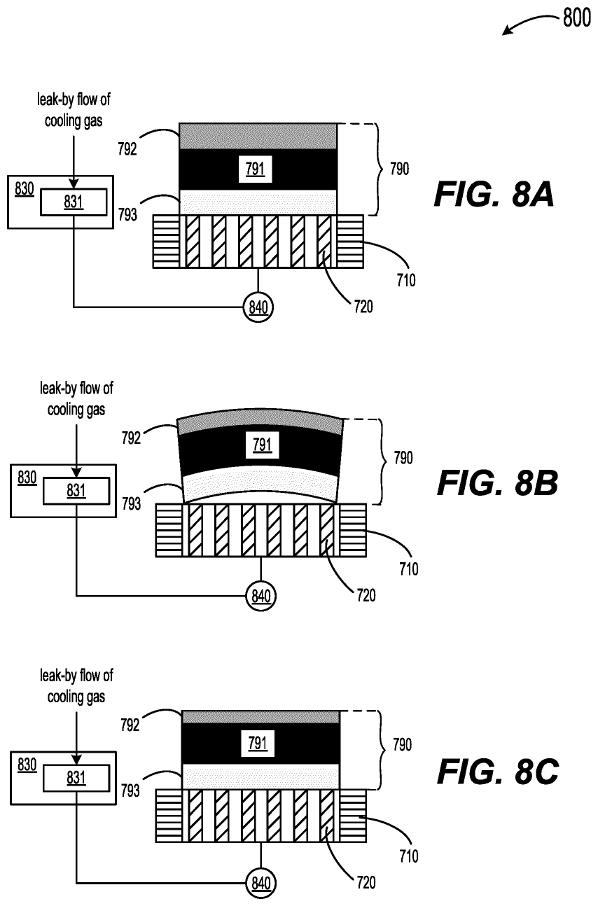

FIGS. 8A-8C are schematic diagrams illustrating an ESC/BSG system 800 according to a second embodiment of the present disclosure. The ESC/BSG system 800 can also help balance out the effect of change in wafer bowing during processing. In an embodiment, the ESC/BSG system 800 can also include the ESC 710 and the BSG cooling device 720. In some embodiments, the ESC/BSG system 800 can further include a monitoring system 830 that is configured to monitor the bowing of a semiconductor structure, e.g., the semiconductor structure 790. In an embodiment, the monitoring system 830 can include a cooling gas leak-by flow gauge 831 that is configured to measure the leak-by flow of a cooling gas (or a backside gas such as He) introduced by the BSG cooling device 720 to the backside of the semiconductor structure 790. The leak-by flow can be measured as a gauge for clamp performance of the ESC to the semiconductor structure 790, which may correspond to the bowing of the semiconductor structure 790.

In an embodiment, the ESC/BSG system 800 can further include a controller (e.g., a processor) 840 that is coupled between the monitoring system 830 and the ESC 710 and the BSG cooling device 720 and configured to control the ESC 710 and/or the BSG cooling device 720 based on the leak-by flow measured and feedbacked by the monitoring system 830. For example, the controller 840 can be configured to control the ESC 710 to adjust the electrostatic voltage in order to adjust the ESC force to clamp the semiconductor structure 790 based on the leak-by flow of the cooling gas (or backside gas). As another example, the controller 740 can be configured to control the BSG cooling device 720 to adjust the flow of the backside gas (or the BSG pressure of the backside gas) based on the leak-by flow of the cooling gas.

In operation of the ESC/BSG system 800, the semiconductor structure 790, which is substantially flat, can be placed onto the ESC 710, as shown in FIG. 8A. As the semiconductor structure 790 is further processed, e.g., the different materials and structural formations 792 being etched and thinned, the stress-modification film 793, which remains on the backside of the substrate 791, now is responsible for creating the bowing of the substrate 791, resulting in the bowing of the semiconductor structure 790, and the monitoring system 830 can monitor the bowing of the semiconductor structure 790 by measuring the leak-by flow of the cooling gas, as shown in FIG. 8B. Accordingly, the controller 840 can control the ESC 710 to adjust the electrostatic voltage to adjust the ESC force and/or control the BSG cooling device 720 to adjust the flow of the backside gas (or the BSG pressure of the backside gas) based on the leak-by flow of the backside gas in order to flatten the semiconductor structure 790, as shown in FIG. 8C.

According to the present disclosure, the backside gas (He) pressure and the electrostatic voltage can be altered individually for every step of a process (e.g., etching) so by gradually changing over many steps or even larger changes over a select few steps, the pressure behind a semiconductor structure can be modified which has a direct impact on the physical distance, and flexion of the semiconductor structure chucked to the ESC. Backside films (e.g., the stress-modification films 130, 530, 630 and 793) alone can only compensate for the current bow state of a semiconductor structure, but changing this knob can dynamically account for changes that evolve over the course of an etch process as the top films (e.g., the different materials and structural formations 120, 520, 620 and 792) are etched. By using a monitoring/feedback system (e.g., the monitoring systems 730 and 830 and the controllers 740 and 840), automatic control can be enabled to keep the best possible chucking and etch surface as the etch progresses and thick stressed films start to warp the semiconductor structure.

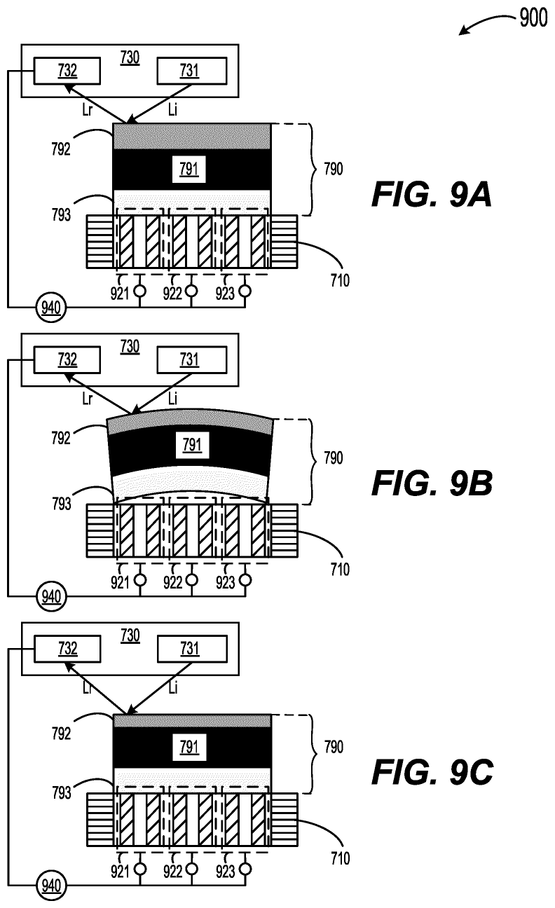

FIGS. 9A-9C are schematic diagrams illustrating an ESC/BSG system 900 according to a third embodiment of the present disclosure. The ESC/BSG system 900 can also help balance out the effect of change in wafer bowing during processing. In an embodiment, the ESC/BSG system 900 can also include the ESC 710 and the monitoring system 730. The ESC/BSG system 900 differs from the ESC/BSG system 700 in that the ESC/BSG system 900 can control the temperature of the semiconductor structure 790 at multiple zones thereof. For example, the ESC/BSG system 900 can further include a controller 940 and multiple BSG cooling devices 921-923 that are controlled by the controller 940 to control the temperature of the semiconductor structure 790 at multiple zones. For example, the controller 940 can control the multiple BSG cooling devices 921-923 to introduce an inert gas with high thermal conductivity, such as helium (He), as a cooling gas at various flows/pressures corresponding to the bow measurements of the semiconductor structure 790 at different zones monitored by the monitoring system 730 to the backside of the semiconductor structure 790.

In operation of the ESC/BSG system 900, the semiconductor structure 790, which may include the stress-modification film 793 formed on the backside of the substrate 791 to counter a stress induced by different materials and structural formations 792 formed on the frontside of the substrate 791 and is substantially flat, can be placed onto the ESC 710, as shown in FIG. 9A. As the semiconductor structure 790 is further processed, e.g., the different materials and structural formations 792 being etched and thinned, the stress-modification film 793, which remains on the backside of the substrate 791, now is responsible for creating the bowing of the substrate 791, resulting in the bowing of the semiconductor structure 790, and the monitoring system 730 can monitor the bowing and identify the bow measurements of the semiconductor structure 790 at multiple zones thereof, as shown in FIG. 9B. Accordingly, the controller 940 can control the ESC 710 to adjust the electrostatic voltage to adjust the ESC force and/or control the BSG cooling devices 921-923 to adjust the flow of the backside gas (or the BSG pressure of the backside gas (He)) based on the bow measurements of the semiconductor structure 790 at multiple zones thereof in order to flatten the semiconductor structure 790, as shown in FIG. 9C.

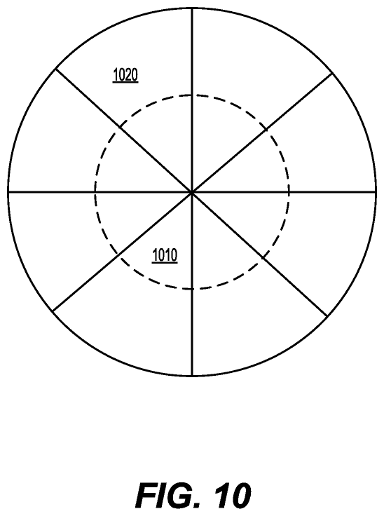

In an embodiment, the multiple zones of the semiconductor structure 790 can be arranged radially/angularly, e.g., including separating radial zones 1010 and angular zones 1020, as shown in FIG. 10, and the BSG cooling devices 921-923 can also be arranged radially/angularly to control the temperature of the semiconductor structure 790 at multiple zones thereof.

In the preceding description, specific details have been set forth, such as a particular geometry of a processing system and descriptions of various components and processes used therein. It should be understood, however, that techniques herein may be practiced in other embodiments that depart from these specific details, and that such details are for purposes of explanation and not limitation. Embodiments disclosed herein have been described with reference to the accompanying drawings. Similarly, for purposes of explanation, specific numbers, materials, and configurations have been set forth in order to provide a thorough understanding. Nevertheless, embodiments may be practiced without such specific details. Components having substantially the same functional constructions are denoted by like reference characters, and thus any redundant descriptions may be omitted.

Various techniques have been described as multiple discrete operations to assist in understanding the various embodiments. The order of description should not be construed as to imply that these operations are necessarily order dependent. Indeed, these operations need not be performed in the order of presentation. Operations described may be performed in a different order than the described embodiment. Various additional operations may be performed and/or described operations may be omitted in additional embodiments.

“Substrate” or “target substrate” as used herein generically refers to an object being processed in accordance with the present disclosure. The substrate may include any material portion or structure of a device, particularly a semiconductor or other electronics device, and may, for example, be a base substrate structure, such as a semiconductor wafer, reticle, or a dielectric layer on or overlying a base substrate structure such as a thin film. Thus, substrate is not limited to any particular base structure, underlying dielectric layer or overlying dielectric layer, patterned or un-patterned, but rather, is contemplated to include any such dielectric layer or base structure, and any combination of dielectric layers and/or base structures. The description may reference particular types of substrates, but this is for illustrative purposes only.

Those skilled in the art will also understand that there can be many variations made to the operations of the techniques explained above while still achieving the same objectives of the present disclosure. Such variations are intended to be covered by the scope of this disclosure. As such, the foregoing descriptions of embodiments of the invention are not intended to be limiting. Rather, any limitations to embodiments of the invention are presented in the following claims.

What is claimed IS:

1. An electrostatic chuck (ESC)/backside gas (BSG) system, comprising:
an ESC configured to generate an electrostatic chucking force (ESC force) according to an electrostatic voltage applied thereto to clamp a semiconductor structure with a backside placed onto the ESC;
at least one BSG cooling device integrated with the ESC, the at least one BSG cooling device configured to introduce to the backside of the semiconductor structure a backside gas at a backside gas pressure (BSG pressure);
a monitoring system configured to monitoring bowing of the semiconductor structure; and
a controller coupled between the monitoring system and the ESC and the at least one BSG cooling device, the controller configured to adjust the BSG pressure at which the backside gas is introduced according to the bowing of the semiconductor structure.

2. The ESC/BSG system of claim 1, wherein the monitoring system includes a light source configured to emit incident light onto a surface of the semiconductor structure, and a light detector configured to receive reflective light from the surface of the semiconductor structure and identify the bowing of the semiconductor structure.

3. The ESC/BSG system of claim 2, wherein the light detector is configured to identify the bowing of the semiconductor structure by measuring z-direction height deviations across the surface of the semiconductor structure.

4. The ESC/BSG system of claim 1, wherein the monitoring system includes a leak-by flow gauge configured to measure a leak-by flow of the backside gas, the leak-by flow measured as a gauge for clamp performance of the ESC to the semiconductor structure that corresponds to the bowing of the semiconductor structure.

5. The ESC/BSG system of claim 1, wherein the controller is further configured to adjust the electrostatic voltage applied to the ESC according to the bowing of the semiconductor structure.

6. The ESC/BSG system of claim 1, wherein the backside gas includes inert gas.

7. The ESC/BSG system of claim 6, wherein the inert gas includes helium (He).

8. The ESC/BSG system of claim 1, wherein the backside gas is used to adjust temperature of the semiconductor structure.

9. The ESC/BSG system of claim 1, wherein the ESC includes an electrode and a dielectric layer that is formed between the electrode and the semiconductor structure, and the electrostatic voltage is applied to the dielectric layer.

10. The ESC/BSG system of claim 1, wherein the at least one BSG cooling device includes multiple BSG cooling devices, and the controller is configured to adjust BSG pressures at which the backside gas is introduced by the multiple BSG cooling devices according to the bowing of the semiconductor structure at multiple zones thereof.

11. An electrostatic chuck (ESC)/backside gas (BSG) system, comprising:
an ESC configured to generate an electrostatic chucking force (ESC force) according to an electrostatic voltage applied thereto to clamp a semiconductor structure with a backside placed onto the ESC;
at least one BSG cooling device integrated with the ESC, the at least one BSG cooling device configured to introduce to the backside of the semiconductor structure a backside gas at a backside gas pressure (BSG pressure);
a monitoring system configured to monitoring bowing of the semiconductor structure; and
a controller coupled between the monitoring system and the ESC and the at least one BSG cooling device, the controller configured to adjust the electrostatic voltage applied to the ESC according to the bowing of the semiconductor structure.

12. The ESC/BSG system of claim 11, wherein the monitoring system includes a light source configured to emit incident light onto a surface of the semiconductor structure, and a light detector configured to receive reflective light from the surface of the semiconductor structure and identify the bowing of the semiconductor structure.

13. The ESC/BSG system of claim 12, wherein the light detector is configured to identify the bowing of the semiconductor structure by measuring z-direction height deviations across the surface of the semiconductor structure.

14. The ESC/BSG system of claim 11, wherein the monitoring system includes a leak-by flow gauge configured to measure a leak-by flow of the backside gas, the leak-by flow measured as a gauge for clamp performance of the ESC to the semiconductor structure that corresponds to the bowing of the semiconductor structure.

15. The ESC/BSG system of claim 11, wherein the controller is further configured to adjust the BSG pressure at which the backside gas is introduced according to the bowing of the semiconductor structure.

16. The ESC/BSG system of claim 15, wherein the at least one BSG cooling device includes multiple BSG cooling devices, and the controller is configured to adjust BSG pressures at which the backside gas is introduced by the multiple BSG cooling devices according to the bowing of the semiconductor structure at multiple zones thereof.

17. The ESC/BSG system of claim 11, wherein the backside gas includes inert gas.

18. The ESC/BSG system of claim 17, wherein the inert gas includes helium (He).

19. The ESC/BSG system of claim 11, wherein the backside gas is used to adjust temperature of the semiconductor structure.

20. The ESC/BSG system of claim 11, wherein the ESC includes an electrode and a dielectric layer that is formed between the electrode and the semiconductor structure, and the electrostatic voltage is applied to the dielectric layer.
